(19) United States
(12) Patent Application Publication
(10) Pub. No.: US 2003/0135802 A1
(43) Pub. Date: Jul. 17, 2003

(54) Verification test method for programmable logic devices

(76) Inventors: Jeff C. Klein, Tucson, AZ (US); James W. Hoare, Tucson, AZ (US); Luis Bonilla, Tucson, AZ (US)

Correspondence Address: HONEYWELL INTERNATIONAL INC., 101 COLUMBIA ROAD, P O BOX 2245, MORRISTOWN, NJ, 07962-2245, US

(21) Appl. No.: 10/046,937

(22) Filed: Jan. 14, 2002

(51) Int. Cl. G01R 31/28

(52) U.S. Cl. 714/725

(57) ABSTRACT

A method of efficiently designing, implementing, and verifying programmed PLDs that includes translating simulation test vectors that are generated by design automation software into device level test vectors. Each of the device level test vectors is substantially identical to one of the simulation test vectors and is readable by automatic testers. Thus, the operation of programmed PLDs can be thoroughly and efficiently verified at the device level using the same test stimuli as a simulation test model.

### BACKGROUND OF THE INVENTION

The present invention relates to the design process for programmable logic devices (PLDs) and, more particularly, to a method of efficiently designing, implementing, and verifying programmed PLDs.

A programmable logic device (PLD) is a general-purpose integrated circuit for implementing logic circuitry. One of the many uses for PLDs is in the control systems on an aircraft. A PLD contains numerous logic circuit elements that can be customized for a particular application. A PLD can be thought of as a collection of logic gates and programmable switches. The programmable switches are selectively “opened” and “closed” to interconnect the various logic gates to implement a desired logic circuit.

Various types of PLDs are commonly known, and the particular PLD type utilized depends, at least in part, on the size and complexity of the logic circuit being implemented. The PLD types most commonly known include programmable logic arrays (PLAs), programmable array logic (PAL) devices, complex programmable logic devices (CPLDs), and field programmable gate arrays (FPGAs). A typical PLA may include a plurality of input buffers and inverters, a plurality of logic AND gates, and a plurality of logic OR gates. The PLA may be programmed to selectively interconnect various of the input buffers and inverters and logic AND gates, and to selectively interconnect various of the AND gates and OR gates. Thus, a programmed PLA outputs a sum-of-products function of the PLA inputs.

A typical PAL device, similar to a typical PLA, may also include a plurality of input buffers and inverters, a plurality of logic AND gates, and a plurality of logic OR gates. However, unlike a PLA, with a typical PAL the OR gates may not be selectively interconnected with various of the AND gates. Instead, these interconnections, which can reduce device performance if they are programmable, are fixed. Thus, as compared to a typical PLA, a typical PAL is simpler to manufacture, less expensive, and offers better performance.

The typical PLAs and PALs described above are useful for implementing relatively small logic circuits. However, if a relatively large logic circuit implementation is required, multiple PLAs or PALs may be used, or the circuit may be implemented using CPLDs or FPGAs. A typical CPLD includes a plurality of input/output (I/O) circuits, and a plurality of logic circuit blocks that may be selectively interconnected by a global interconnection matrix. Each of the logic circuit blocks may be constructed similar to a PLA or PAL. Thus, a typical CPLD can be viewed as having two levels of programmability. That is, each circuit block is programmable, and the interconnections between the circuit blocks are programmable.

A typical FPGA includes a plurality of I/O circuits, a plurality of configurable logic circuit blocks arranged in a two-dimensional array, and a plurality of interspersed switches organized as horizontal and vertical routing channels between rows and columns of the configurable logic circuit blocks. Similar to a typical CPLD, a typical FPGA can be viewed as having two levels of programmability. Each logic circuit block may be individually programmed to perform a particular logic function, and the switches may be programmed to selectively interconnect the logic blocks.

Before installing a PLD in a system, its design and operation should be verified. In the past, this verification process included testing a simulated model of the PLD to verify proper PLD design, and then testing the actual programmed PLD after it is installed in the system to verify its operation. The simulated model testing uses numerous simulation test vectors (e.g., there is a potential for millions of test vectors) that are generated using design automation software to simulate various input data, and then checks the simulated model output to ensure it functioned properly. For in-system testing, the PLD and various points within the system are instrumented and test signals are supplied to the PLD inputs. This in-system testing is relatively labor intensive, time consuming, and costly. In addition, because all of the simulation test vectors may not have been repeated (due to the large number of test vectors), some uncertainty remained in the operational verification.

Recently, various certification authorities have published more stringent requirements for verifying proper design and operation of PLDs. These new requirements include comprehensive PLD operation verification at the device level. Currently, this device level testing is conducted using automated test equipment and a separate set of device level test vectors. These device level test vectors are independently generated using a different set of software tools and are input to the automated test equipment. Again, due to the large number of simulation test vectors that are generated by the automated design software, the likelihood of manually reproducing the simulation test vectors for device level testing is quite small. Additionally, the time it takes to independently generate the device level test vectors is time intensive and potentially costly.

Hence, there is a need for a method of verifying proper design and operation of programmed PLDs that is less labor intensive, and/or is less time consuming, and/or provides cost savings over known methods. The present invention addresses one or more of these needs.

### SUMMARY OF THE INVENTION

The present invention provides a method of verifying proper design and operation of programmed PLDs in which device level test vectors that are substantially identical to simulation test vectors are generated during the PLD design process. These device level test vectors are in a format that is readable by automated test equipment and, therefore, PLD operation can be verified in accordance with more stringent standards with less labor, and/or in less time, and/or with less cost.

In one embodiment of the present invention, and by way of example only, a method of verifying proper design and operation of a programmed PLD utilizing a PLD test device includes developing, translating, and testing steps. The developing step includes developing at least one simulation test vector that is used to test a simulated model of the programmed PLD using a design automation software tool. The translating step includes translating at least one simulation test vector into at least one device level test vector that is in a format readable by the PLD test device. The testing step includes testing the programmed PLD in the PLD test device using each of the device level test vectors to obtain device level test results.

In another exemplary embodiment of the present invention, a method of designing, implementing, and verifying proper operation of programmed PLDs includes developing, synthesizing, implementing, translating, and testing steps. One developing step includes developing a software model of the programmed PLD using a design automation software tool. The synthesizing step includes synthesizing the software model of the programmed PLD using a design synthesis software tool. The implementing step includes implementing the programmed PLD based on the synthesized software model. Another developing step includes developing at least one simulation test vector that is used to test a simulated model of the programmed PLD using the design automation software tool. The translating step includes translating at least one simulation test vector into at least one device level test vector that is in a format readable by a PLD test device. The testing step includes testing the programmed PLD in the PLD test device using each of the device level test vectors to obtain device level test results.

Other independent features and advantages of the preferred method will become apparent from the following detailed description, taken in conjunction with the accompanying drawings which illustrate, by way of example, the principles of the invention.

### BRIEF DESCRIPTION OF THE DRAWINGS

FIG. 1 is a flowchart illustrating the overall programmable logic device design process according to an embodiment of the present invention;

FIG. 2 is a flowchart depicting various steps of the design phase of the overall process depicted in FIG. 1;

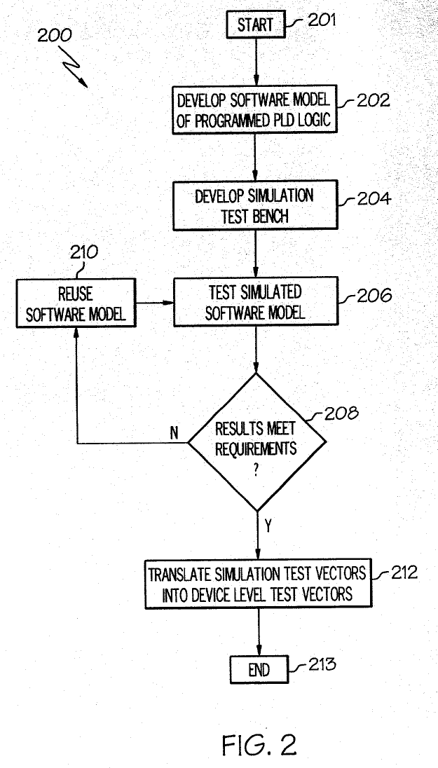

FIG. 3 is a flowchart depicting various steps of the implementation phase of the overall process depicted in FIG. 1;

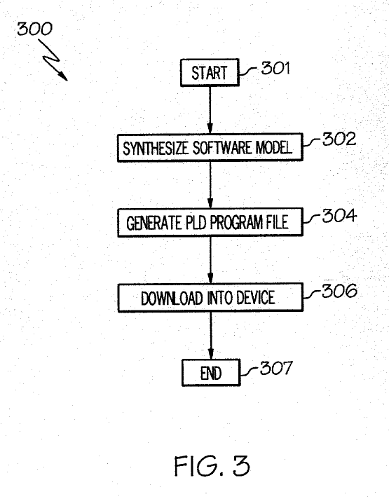

FIG. 4 is a flowchart depicting various steps of the verification phase of the overall process depicted in FIG. 1;

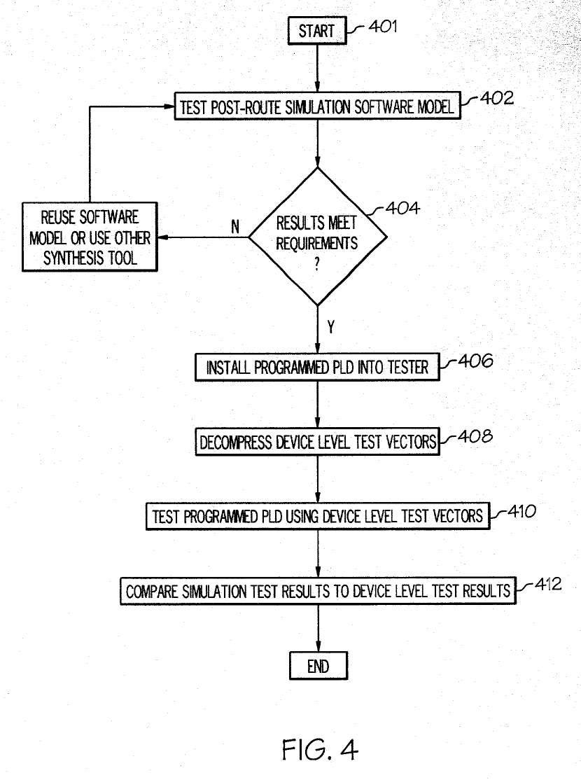

FIG. 5 illustrates the interrelationships of the various processes depicted in FIGS. 2, 3, and 4 to make up the overall design process depicted in FIG. 1; and

FIG. 6 is a flowchart depicting the operational steps carried out by a simulation test vector software translation tool used in the process depicted in FIG. 1.

### DETAILED DESCRIPTION OF THE PREFERRED EMBODIMENT

Before building a new electrical or electronic system, a set of functional requirements are developed to describe the desired overall function of the system. Based on these functional requirements, system and circuit designers collaborate and determine how to architect the system. In other words, the designers decide which of the system requirements will be satisfied with a particular type of hardware.

In some cases, more particularly those systems that are implemented using digital technology, the system may include one or more programmable logic devices (PLDs). For example, a PLD may be used to interface a main processor with other parts of the system, or a PLD may be used to implement stand-alone functional requirements such as, for example, an overspeed trip function or watchdog timer. In any event, once it is decided that one or more functions will be implemented using PLDs, the circuit designers begin working on the design for each specific PLD.

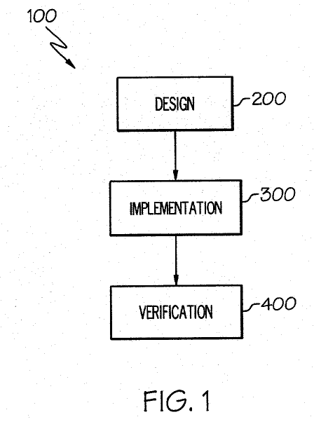

The overall design process for a PLD according to an embodiment of the present invention is depicted in FIG. 1. This overall design process 100 includes three major phases, a design phase 200, an implementation phase 300, and a verification phase 400. It is to be appreciated that each of these phases, while depicted in FIG. 1 as being sequential, include steps that are performed in parallel with steps of other phases. In any case, in the design phase 200, the source code used to describe, simulate, and test the overall functionality of the PLD is developed. In the implementation phase 300, the source code is synthesized and is used to program the PLD. In the verification phase 400, the synthesized source code is tested and the programmed PLD is tested. Each of these different phases will now be discussed in more detail.

The first step in the PLD design phase 200 is to develop a software model of the programmed PLD logic that describes the overall functionality that the PLD will implement 202. This is done using any one of numerous design automation software tools, such as VHDL and Verilog; preferably, however, VHDL is used. As is generally known, VHDL stands for Very High Speed Integrated Circuit (VHSIC) Hardware Description Language, and is a programming language that is used to describe the overall behavior of a digital system or circuit. Similar to high-level programming languages, such as Pascal, C, and C++, that allow complex design concepts to be expressed as computer programs, VHDL is a general-purpose programming language that allows designers to describe the behavior of complex circuits. This software description is in a format that allows automatic circuit synthesis and circuit simulation, both of which are described more fully below.

Followed closely after, or in parallel with, the programmed PLD logic software model development 202, is the development of one or more so-called “simulation test benches” 204. A simulation test bench is a software description of various PLD circuit stimuli and corresponding expected results files (so-called simulation test vectors) that allow designers to test PLD circuit design functionality in a simulated test environment. Thus, before a PLD is physically programmed, a simulated model of the programmed PLD can be tested to ensure that it will function as it is designed. Preferably, the test benches are written using the same design automation software tool used to develop the programmed PLD logic software model (e.g., VHDL). It is noted that when the test benches are written, each is preferably written in separate test sections, which allows each functional section of the PLD to be individually tested and the test results to be individually tracked.

Once the programmed PLD logic software model and the simulation test bench are developed, a simulated model of the programmed PLD is tested 206. This is accomplished by translating the developed software model into the simulated model of the programmed PLD using a simulation software tool and, using this same software tool, subjecting the simulated model to testing using the test bench simulation test vectors. The results of the simulation test are then checked 208. If the software model does not meet the design requirements, the PLD logic software model is revised 210, and the simulation test 206 is repeated until the software model passes. Any one of numerous known software tools may be used to simulate the software model. In a particular preferred embodiment, the simulation software tool is one that is developed by Aldec®, Incorporated. Preferably, though certainly not necessarily, the simulation test vector translation program is run concurrently with the simulation test bench in this simulation environment.

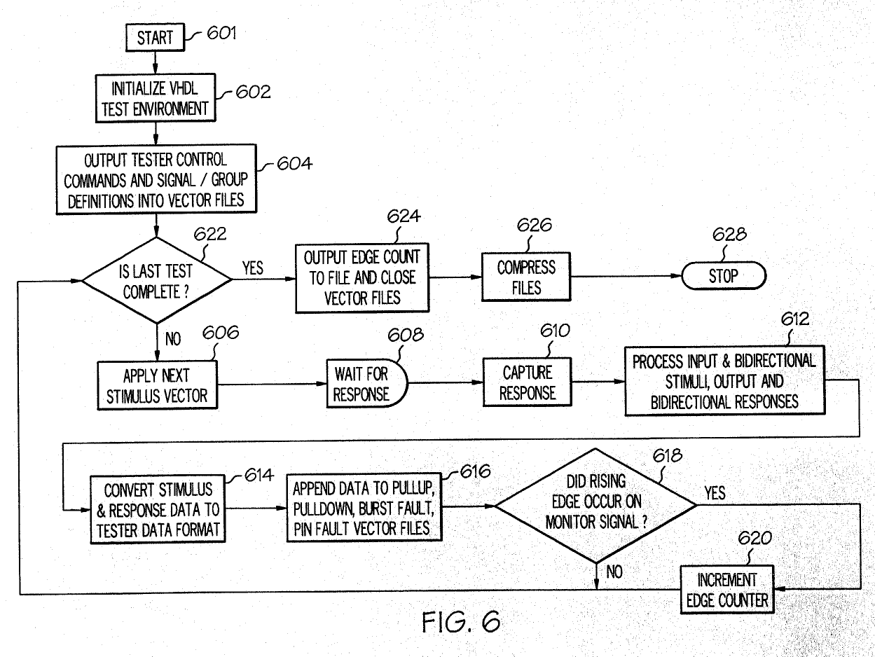

Along with the simulation test bench development 204, a specialized simulation test vector translation program is also developed. This translation program runs along with the simulation test bench during the simulation testing of the programmed PLD, and translates each of the simulation test vectors into device level test vectors that are readable by an automatic test device. The process carried out by a particular preferred embodiment of a translation program is depicted in FIG. 6, and will now be described in detail. The program 600 first initializes the test environment 602. To do this, each of the simulation test files is placed into a file directory and compiled into an object code that runs when the simulation is begun. Once the simulation is begun, various variables and signals used to control the sequencing of the simulation are initialized. For each test vector file that is to be created, the program then supplies various header information 604 that is needed by the automated test equipment so that the test equipment can readily discern the meaning of the test vector data with respect to the location on the actual programmed PLD. For example, the pin location of each signal on the device, the type of signal (e.g., whether it is an input, an output, or a bi-directional signal), and what voltage levels are to be applied and sensed for high and low logic levels, etc. The simulation test vectors are then applied, one at a time, to the simulated model of the programmed PLD 606.

As each simulation test vector is applied, the simulator awaits the response of the simulated model 608, if a delay is programmed into the simulation test bench. It is noted that a such a delay need not be included, but is provided in a preferred embodiment for simulation testing at the gate level of the programmed PLD model. When the response is received, it is captured 610 and, along with the input stimulus, is appropriately processed 612. During this processing 612, the captured data is appropriately categorized as to whether it represents an input or bi-directional stimulus, or an output or bi-directional response, to ensure proper application of the stimulus and monitoring of the response during the actual testing of the programmed PLD.

Thereafter, the processed simulation test vector data is translated into a device level test vector that is in a format readable by the automated test equipment that will be used to test the actual programmed PLD 614. Each of the device level test vectors is substantially an exact representation of each of the simulation test vectors that is used to test the simulated model of the programmed PLD. These device level test vectors are output, as appropriate, into one or more vector files, depending on the specific automated test equipment being used 616. In a particular preferred embodiment, there are four different files, a pull-up vector file, a pull-down vector file, a burst fault vector file, and a pin fault vector file. As is known, the pull-up and pull-down vector files allow tri-state signal testing. Specifically, during a pull-up test, the automated test equipment applies a pull-up to all pins, and during a pull-down test, the test equipment applies a pull-down to all pins. A burst fault vector file (which duplicates exactly the pull-up vector file, except that incorrect response data is periodically inserted in the test vector data) is used to ensure that the test system is operating properly and can detect and report failures accurately. A pin fault vector file includes at least one test vector with incorrect response data for each pin on the programmed PLD, and is used to ensure that the test system can detect faults that occur on any pin of the PLD, as a result of either an incorrect application of the stimulus or an incorrect response of the PLD.

During the simulation, the program 600 also monitors the highest edge rate signal in the test, which is typically the high-speed clock driving the PLD 618. This is done to verify that, during the test, actual testing is being accomplished. If the rising edge does occur, then a counter is incremented 620. This count keeps track of the number of clock cycles associated with each test vector file. The cycle is then repeated until it is determined that all of the simulation test vectors have been used, meaning the test is complete 622. Once the test is complete, the edge count is output to a separate count file, and the pull-up, pull-down, burst fault, and pin fault vector files are closed 624. Depending upon the size and number of device level test vectors, the files containing these device level test vectors may be compressed using any one of numerous known compression software tools 626.

After the design phase 200 is complete, or in parallel with at least portions of the design phase 200, the implementation phase 300 is begun. In the implementation phase 300, the programmed PLD logic software model is synthesized using a design synthesis software tool 302. The design synthesis software tool may be any one of numerous synthesis software tools known in the art. In a preferred embodiment, this tool is one that is developed and marketed by Xilinx®, Incorporated. As is generally known, the synthesis software tool transforms the text-based format of the programmed PLD logic software model into a logic-based equivalent PLD program file 304. The PLD program file includes a netlist, which is a description of the various logic gates and interconnections that are used to implement the logic design. The PLD program file may then be downloaded into the physical PLD to implement the programmed PLD logic 306.

At this point, or in parallel with portions of the previous phases, the verification phase 400 is begun. During this phase, the design is tested to verify that it meets the specified functional requirements. This verification testing may include both simulation testing and actual physical testing of the programmed PLD design. Though, at a minimum actual physical testing of the programmed PLD is tested. If the verification phase 400 includes simulation testing, this simulation testing is conducted on a post-synthesis simulated model of the programmed PLD 402. This post-synthesis model, referred to as a “post-route” model, is a gate level model of the programmed PLD logic, and is generated by the synthesis software tool. A simulation software tool, which may be the same tool that is used to test the programmed PLD logic software model during the design phase 200, uses the same simulation test vectors developed as part of the test bench as stimuli for this simulation testing. These post-synthesis simulation test results are checked to determine whether or not the PLD program file generated by the synthesis software tool functions the same as the programmed PLD logic software model. If this simulation test fails, then the PLD logic software model may need to be revised, and various portions of the design 200, implementation 300, and verification 400 phases repeated.

To test the actual programmed PLD, it is mounted on a custom circuit board and is installed into an automatic tester 406. If the PLD is reprogrammable, it may be hard-mounted to this circuit board and programmed while installed on the circuit board, or, if it is one-time-programmable (OTP), a socket may be utilized for ease of replacement. The automatic tester may be any one of numerous known test devices known in the art for testing PLDs. For example, in a preferred but non-limiting embodiment, the automated tester is a device manufactured by GenRad®, Incorporated. Once the PLD is installed in the automatic tester, it is then tested using the device level test vectors 410. As was noted above, the files containing these device level test vectors may be compressed and, if so, are first decompressed 408 and then input to the automatic tester to apply the device level test vectors to the programmed PLD. The results of the test stimuli are then automatically compared to the results from the simulation test and, if they are equivalent, the programmed PLD is verified at the device level.

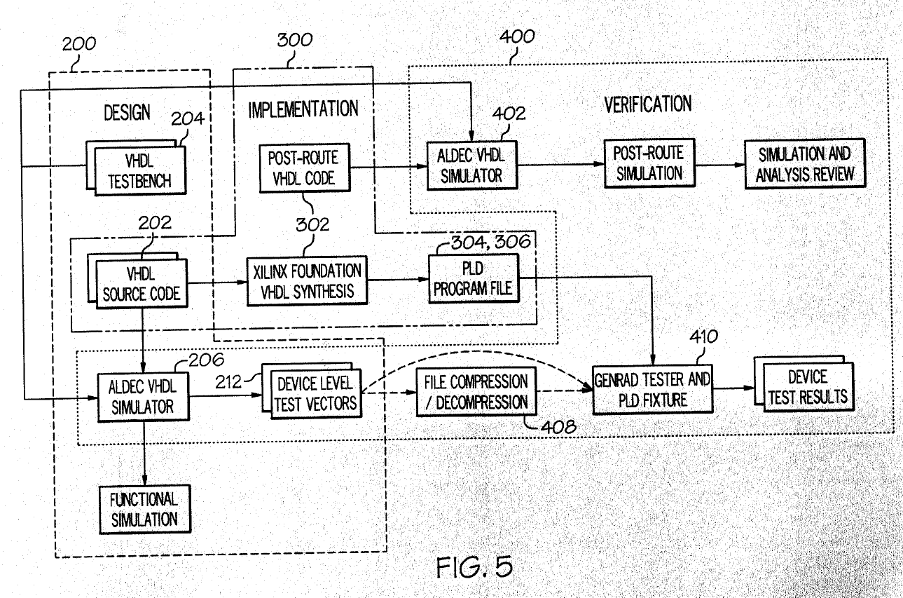

Although the design 200, implementation 300, and verification 400 phases have been somewhat described as individual phases, it will be appreciated that this was done only for the sake of convenience. In reality, each of these phases includes steps that overlap with one another. This can be seen more clearly with reference to FIG. 5, which depicts the interrelationships of the various phases of the overall design process, showing the overlap among the design 200, implementation 300, and verification 400 phases.

With the present embodiment, the simulation test vectors used to test a simulated model of the programmed PLD are translated into device level test vectors that are substantially exact representations of the simulation test vectors. These device level test vectors in turn are used to test an actual programmed PLD. The simulation test vectors are numerous, in certain cases running upwards of tens of millions of test vectors. Since the device level test vectors are translated from the simulation test vectors in a format readable by an automatic tester, the programmed PLD's operation can be verified using this same number of test vectors at the device level in a relatively short period of time. For example, a programmed PLD can be tested with a million or more device level test vectors in a matter of minutes.

While the invention has been described with reference to a preferred embodiment, it will be understood by those skilled in the art that various changes may be made and equivalents may be substituted for elements thereof without departing from the scope of the invention. In addition, many modifications may be made to adapt to a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

We claim:

1. A method of verifying proper design and operation of a programmed programmable logic device (PLD) utilizing a PLD test device, comprising:
developing at least one simulation test vector using a PLD design automation software tool, each simulation test vector used to test a simulated model of the programmed PLD;
translating at least one simulation test vector into at least one device level test vector that is in a format readable by the PLD test device; and
testing the programmed PLD in the PLD test device using each of the device level test vectors to obtain device level test results.

2. The method of claim 1, wherein all of the simulated test vectors are translated into a corresponding device level test vector.

3. The method of claim 1, further comprising:
testing the simulated model of the programmed PLD using each of the simulation test vectors to obtain simulation test results; and
comparing the simulation test results with the device level test results.

4. The method of claim 1, further comprising:
developing a software model of the programmed PLD using the design automation software tool; and
translating the software model of the programmed PLD into the simulated model of the programmed PLD using a simulation software tool.

5. The method of claim 4, wherein the simulation software tool translates the simulation test vectors into the device level test vectors.

6. The method of claim 5, wherein each of the device level test vectors include stimulus data and expected results data.

7. The method of claim 1, further comprising:
generating at least one data file; and
storing each of the device level test vectors in the data files.

8. The method of claim 7, further comprising:
compressing the data files;
storing the compressed data files on a memory storage device; and
decompressing the compressed data files to recover the device level test vectors.

9. The method of claim 1, further comprising:
developing a software model of the programmed PLD using a design automation software tool; and
synthesizing the software model of the programmed PLD using a design synthesis software tool.

10. The method of claim 9, further comprising:
generating a PLD program file from the synthesized software model.

11. The method of claim 10, further comprising:
downloading the PLD program file into an integrated PLD circuit to create the programmed PLD.

12. The method of claim 1, further comprising:
developing a software model of the programmed PLD using a design automation software tool;
synthesizing the software model of the programmed PLD using a design synthesis software tool;
translating the synthesized software model into a post-synthesis simulated model of the programmed PLD using the simulation software; and
testing the post-synthesis simulated model of the programmed PLD using each of the simulation test vectors to obtain post-synthesis simulation test results.

13. A method of verifying proper design and operation of a programmed programmable logic device (PLD) utilizing a PLD test device, comprising:
developing at least one simulation test vector using PLD a design automation software tool, each simulation test vector useful for testing a simulated model of the programmed PLD;
translating at least one simulation test vector into at least one device level test vector that is in a format readable by the PLD test device;
testing the programmed PLD in the PLD test device using each of the device level test vectors to obtain device level test results;
testing the simulated model of the programmed PLD using each of the simulation test vectors to obtain simulation test results; and
comparing the simulation test results with the device level test results.

14. The method of claim 13, wherein all of the simulated test vectors are translated into a corresponding device level test vector.

15. The method of claim 13, further comprising:
developing a software model of the programmed PLD using the design automation software tool; and
translating the software model of the programmed PLD into the simulated model of the programmed PLD using a simulation software tool.

16. The method of claim 15, wherein the simulation software tool translates the simulation test vectors into the device level test vectors.

17. The method of claim 16, wherein each of the device level test vectors include stimulus data and expected results data.

18. The method of claim 13, further comprising:
generating at least one data file; and
storing each of the device level test vectors in the data files.

19. The method of claim 18, further comprising:
compressing the data files;
storing the compressed data files on a memory storage device; and
decompressing the compressed data files to recover the device level test vectors.

20. The method of claim 13, further comprising:
developing a software model of the programmed PLD using a design automation software tool; and
synthesizing the software model of the programmed PLD using a design synthesis software tool.

21. The method of claim 20, further comprising:
generating a PLD program file from the synthesized software model.

22. The method of claim 21, further comprising:
downloading the PLD program file into an integrated PLD circuit to create the programmed PLD.

23. The method of claim 13, further comprising:
developing a software model of the programmed PLD using a design automation software tool;
synthesizing the software model of the programmed PLD using a design synthesis software tool;
translating the synthesized software model into a post-synthesis simulated model of the programmed PLD using the simulation software; and
testing the post-synthesis simulated model of the programmed PLD using each of the simulation test vectors to obtain post-synthesis simulation test results.

24. A method of verifying proper design and operation of a programmed programmable logic device (PLD) utilizing a PLD test device, comprising:
developing a software model of the programmed PLD using a design automation software tool;
translating the software model of the programmed PLD into a simulated model of the programmed PLD using a simulation software tool;
developing at least one simulation test vector using PLD the design automation software tool, each simulation test vector used to testing the simulated model of the programmed PLD;
translating at least one simulation test vector into at least one device level test vector that is in a format readable by a PLD test device;
testing the programmed PLD in the PLD test device using each of the device level test vectors to obtain device level test results;
testing the simulated model of the programmed PLD using each of the simulation test vectors to obtain simulation test results; and
comparing the simulation test results with the device level test results.

25. A method of designing, implementing, and verifying proper operation of programmed programmable logic devices (PLDs), comprising:
developing a software model of the programmed PLD using a design automation software tool;
synthesizing the software model of the programmed PLD using a design synthesis software tool;
implementing the programmed PLD based on the synthesized software model;
developing at least one simulation test vector using the design automation software tool, each simulation test vector useful for testing a simulated model of the programmed PLD;
translating each simulation test vector into at least one device level test vector that is in a format readable by a PLD test device; and
testing the programmed PLD in the PLD test device using each of the device level test vectors to obtain device level test results.

26. The method of claim 25, wherein all of the simulated test vectors are translated into a corresponding device level test vector.

27. The method of claim 25, further comprising:
testing the simulated model of the programmed PLD using each of the simulation test vectors to obtain simulation test results; and
comparing the simulation test results with the device level test results.

28. The method of claim 25, further comprising:
translating the software model of the programmed PLD into the simulated model of the programmed PLD using a simulation software tool.

29. The method of claim 28, wherein the simulation software tool translates the simulation test vectors into the device level test vectors.

30. The method of claim 25, wherein each of the device level test vectors includes stimulus data and expected results data.

31. The method of claim 25, further comprising:
generating at least one data file; and
storing each of the device level test vectors in the data files.

32. The method of claim 31, further comprising:
compressing the data files;
storing the compressed data files on a memory storage device; and
decompressing the compressed data files to recover the device level test vectors.

33. The method of claim 25, wherein the step of implementing the programmed PLD comprises:
generating a PLD program file from the synthesized software model; and
downloading the PLD program file into an integrated PLD circuit to create the programmed PLD.

34. The method of claim 25, further comprising:
translating the synthesized software model into a post-synthesis simulated model of the programmed PLD using the simulation software; and
testing the post-synthesis simulated model of the programmed PLD using each of the simulation test vectors to obtain post-synthesis simulation test results.

35. A method of designing, implementing, and verifying proper operation of programmed programmable logic devices (PLDs), comprising:
developing a software model of the programmed PLD using a design automation software tool;
synthesizing the software model of the programmed PLD using a design synthesis software tool;
implementing the programmed PLD based on the synthesized software model;
developing at least one simulation test vector using the design automation software tool, each simulation test vector useful for testing a simulated model of the programmed PLD;
translating at least one simulation test vector into at least one device level test vector that is in a format readable by a PLD test device;
testing the simulated model of the programmed PLD using each of the simulation test vectors to obtain simulation test results;
testing the programmed PLD in the PLD test device using each of the device level test vectors to obtain device level test results; and
comparing the simulation test results with the device level test results.

36. A method of translating simulation test vectors used to test a simulated model of a programmed programmable logic device (PLD) into device level test vectors used to test the programmed PLD, the method comprising:
applying at least one simulation test vector to a simulated model of the programmed PLD;
capturing a response of the simulated model to the applied simulation test vector; and
converting the simulation test vector and captured response into a format readable by a PLD test device.

37. The method of claim 36, further comprising:
categorizing the simulation test vector as one of an input stimulus and a bi-directional stimulus; and
categorizing the captured response as one of an output response and a bi-directional response.

38. The method of claim 36, further comprising:
outputting the simulation test vector to a predetermined file.

39. The method of claim 38, wherein the predetermined file is one of a pull-up file, a pull-down file, a burst fault file, and a pin fault file.

40. The method of claim 36, further comprising:
monitoring an occurrence of a rising edge of a predetermined signal; and
incrementing a counter with each occurrence of the rising edge to obtain a total count.

41. The method of claim 40, further comprising:
outputting the total count to a count file.

42. A computer implemented system for translating simulation test vectors used to test a simulated model of a programmed programmable logic device (PLD) into device level test vectors used to test the programmed PLD, the system comprising:
means for applying at least one simulation test vector to a simulated model of the programmed PLD;
means for capturing a response of the simulated model to the applied simulation test vector; and
means for converting the simulation test vector and captured response into a format readable by a PLD test device.

43. The system of claim 42, further comprising:
means for categorizing the simulation test vector as one of an input stimulus and a bi-directional stimulus; and
categorizing the captured response as one of an output response and a bi-directional response.

44. The system of claim 42, further comprising:
means for outputting the simulation test vector to a predetermined file.

45. The system of claim 44, wherein the predetermined file is one of a pull-up file, a pull-down file, a burst fault file, and a pin fault file.

46. The system of claim 42, further comprising:
means for monitoring an occurrence of a rising edge of a predetermined signal; and
means for incrementing a counter with each occurrence of the rising edge to obtain a total count.

47. The system of claim 46, further comprising:
outputting the total count to a count file.

48. A computer-readable storage medium containing computer executable code for instructing a computer to perform steps that translate simulation test vectors used to test a simulated model of a programmed programmable logic device (PLD) into device level test vectors used to test the programmed PLD, the steps comprising:
applying at least one simulation test vector to a simulated model of the programmed PLD;
capturing a response of the simulated model to the applied simulation test vector; and
converting the simulation test vector and captured response into a format readable by a PLD test device.

49. The storage medium of claim 48, further comprising the steps of:
categorizing the simulation test vector as one of an input stimulus and a bi-directional stimulus; and
categorizing the captured response as one of an output response and a bi-directional response.

50. The storage medium of claim 48, further comprising the steps of:
outputting the simulation test vector to a predetermined file.

51. The storage medium of claim 50, wherein the predetermined file is one of a pull-up file, a pull-down file, a burst fault file, and a pin fault file.

52. The storage medium of claim 48, further comprising the steps of:
monitoring an occurrence of a rising edge of a predetermined signal; and
incrementing a counter with each occurrence of the rising edge to obtain a total count.

53. The storage medium of claim 52, further comprising the steps of:
outputting the total count to a count file.
